(19) United States
(12) Patent Application Publication
(10) Pub. No.: US 2024/0423008 A1
(43) Pub. Date: Dec. 19, 2024

(54) ORGANIC LIGHT-EMITTING DISPLAY PANELS AND DISPLAY DEVICES

(71) Applicant: SHENZHEN CHINA STAR OPTOELECTRONICS SEMICONDUCTOR DISPLAY TECHNOLOGY CO., LTD., Shenzhen (CN)

(72) Inventors: Zhaoyang XI, Shenzhen (CN); Shuren ZHANG, Shenzhen (CN)

(21) Appl. No.: 18/457,954

(22) Filed: Aug. 29, 2023

(30) Foreign Application Priority Data
Jun. 14, 2023 (CN) 202310704479.6

(51) Int. Cl. H10K 50/13; H10K 50/15; H10K 50/16

(52) U.S. Cl. CPC H10K 50/131; H10K 50/156; H10K 50/166; H10K 2101/30; H10K 2102/351

(57) ABSTRACT

Organic light-emitting display panels and display devices are provided. The organic light-emitting display panel includes an anode, a cathode, a plurality of quantum well units stacked between the anode and the cathode, and a charge generation layer. Each quantum well unit includes a light-emitting layer and barrier layers disposed on both sides of the light-emitting layer. The charge generation layer is disposed between two adjacent ones of the plurality of quantum well units, is configured to inject electrons into the light-emitting layers some of the quantum well units located on a side of the charge generation layer, and is configured to inject holes into the light-emitting layers of some of the quantum well units located on another side of the charge generation layer.

### CROSS-REFERENCE TO RELATED APPLICATION

This application claims priority to Chinese Patent Application No. 202310704479.6, filed on Jun. 14, 2023, the disclosure of which is incorporated herein by reference in its entirety.

### TECHNICAL FIELD

The present disclosure relates to the field of display technologies, and in particular, to organic light-emitting display panels and display devices.

### BACKGROUND

For quantum dot light-emitting diodes in organic light-emitting display panels, holes and electrons are injected and transported from an anode and a cathode, respectively, and then reach a light-emitting layer after passing through a hole transport layer and an electron transport layer for composite luminescence. In related art, the holes and electrons are completely confined in the light-emitting layer by arranging multiple stacked quantum well units. However, the increase in a number of the quantum well units increases a transmission barrier of the device, which cause it more and more difficult for holes and electrons to transport, resulting in carrier equilibrium being broken and reducing device efficiency.

Therefore, there is an urgent need for organic light-emitting display panels and display devices to solve the above technical problems.

### SUMMARY

In view of above, organic light-emitting display panels are provided according to embodiments of the present disclosure. The organic light-emitting display panel includes an anode, a cathode, a plurality of quantum well units stacked between the anode and the cathode, and a charge generation layer; each quantum well unit includes a light-emitting layer and barrier layers disposed on both sides of the light-emitting layer; the charge generation layer is disposed between two adjacent ones of the plurality of quantum well units, is configured to inject electrons into the light-emitting layers some of the quantum well units located on a side of the charge generation layer, and is configured to inject holes into the light-emitting layers of some of the quantum well units located on another side of the charge generation layer.

Display devices are further provided according to embodiments of the present disclosure. The display device includes the above-mentioned organic light-emitting display panel.

### BRIEF DESCRIPTION OF THE DRAWINGS

FIG. 1 is a schematic view of a cross-sectional structure of a first organic light-emitting display panel according to an embodiment of the present disclosure.

FIG. 2 is a schematic view of a cross-sectional structure of a second organic light-emitting display panel according to an embodiment of the present disclosure.

FIG. 3 is a schematic view of a cross-sectional structure of a charge generation layer according to an embodiment of the present disclosure.

FIG. 4 is a schematic view of a cross-sectional structure of the organic light-emitting display panel in FIG. 2 including six quantum well units.

FIG. 5 is a schematic view of a cross-sectional structure of a third organic light-emitting display panel according to an embodiment of the present disclosure.

FIG. 6 is a schematic view of a cross-sectional structure of the organic light-emitting display panel in FIG. 5 including six quantum well units.

FIG. 7 is a schematic view of a cross-sectional structure of a fourth organic light-emitting display panel according to an embodiment of the present disclosure.

FIG. 8 is a schematic view of a first cross-sectional structure of the organic light-emitting display panel in FIG. 7 including six quantum well units.

FIG. 9 is a schematic view of a second cross-sectional structure of the organic light-emitting display panel in FIG. 7 including six quantum well units.

### DETAILED DESCRIPTION

Technical solutions in the embodiments of the present disclosure will be clearly and completely described below with reference to the accompanying drawings. Obviously, the described embodiments are only some of the embodiments of the present disclosure, not all of them. Based on the embodiments in the present disclosure, all other embodiments obtained by those skilled in the art without making creative efforts belong to the scope of protection of this application. In addition, it should be understood that the specific implementations described here are only used to illustrate and explain the present disclosure, and are not intended to limit the present disclosure. In the present disclosure, unless stated to the contrary, the orientation terms such as “up” and “down” generally refer to up and down in an actual use or working state of the devices, and the terms “inside” and “outside” refer to an outline of an installation.

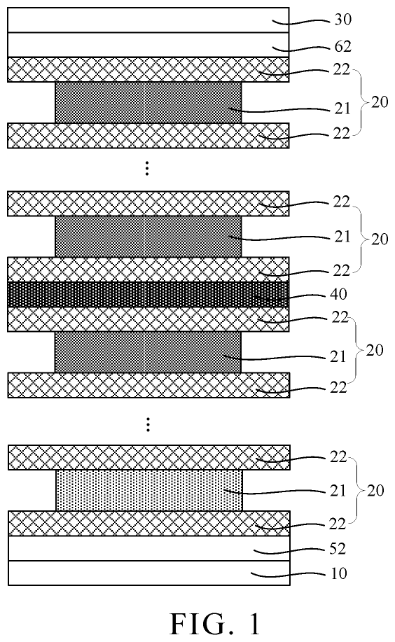

Referring to FIG. 1, an organic light-emitting display panel is provided according to an embodiment of the present disclosure. The organic light-emitting display panel includes an anode 10, a cathode 30, and a charge generation layer 40. The cathode 30 and the anode 10 are oppositely arranged. A plurality of quantum well units 20 are stacked between the anode 10 and the cathode 30. Each of the quantum well units 20 includes a light-emitting layer 21 and barrier layers 22 disposed on both sides of the light-emitting layer 21. The barrier layer 22 is configured to limit a movement area and an energy range of carriers (electrons or holes) in the quantum well unit 20. The charge generation layer 40 is disposed between two adjacent ones of the plurality of quantum well units 20, is configured to inject the electrons into the light-emitting layers 21 of at least some of the quantum well units 20 located on a side of the charge generation layer 40, and is configured to inject the holes into the light-emitting layers 21 of at least some of the quantum well units 20 located on another side of the charge generation layer 40.

It should be noted that the display luminescence mechanism of the organic light-emitting display panels in the embodiments of the present disclosure are described as following.

When a high voltage is applied to the anode 10, and a low voltage is applied to the cathode 30, carriers (including holes and electrons) are injected from the cathode 30 and the anode 10 under an action of an applied electric field. Specifically, the holes are injected from the anode 10 and transmitted to the light-emitting layers 21 of at least some of the quantum well units 20, the electrons are injected from the cathode 30 and transmitted to the light-emitting layers 21 of at least some of the quantum well units 20, and the holes and the electrons are recombined within the light-emitting layers 21 to form excitons. Furthermore, a voltage is applied to the charge generation layer 40, so that under an action of an applied electric field, the charge generation layer 40 separates the holes and the electrons and injects the holes and the electrons from the charge generation layer 40 into the light-emitting layers 21 of at least some of the quantum well units 20 located on both sides of the charge generation layer 40. When the holes and the electrons meet each other, they recombine to form excitons in the light-emitting layers 21. The excitons formed above migrate under an action of the electric field to correspondingly transfer energy to an organic light-emitting material of the light-emitting layers 21, and the organic light-emitting material generates photons to realize display luminescence of the organic light-emitting display panel.

Embodiments of the present disclosure adopt a design of adding the charge generation layer 40 to inject the holes and the electrons into the light-emitting layers 21 of some of the quantum well units 20. Based on this design, the holes and the electrons injected from the anode 10 and the cathode 30 do not need to be transmitted to each of the light-emitting layers 21 of the quantum well units 20, so that a transmission difficulty of the holes and the electrons is relieved, and a driving current of the device is reduced, which is conducive to maintaining a carrier balance in the light-emitting layer 21, thereby improving the device efficiency and the lifetime of the organic light-emitting display panel.

In embodiments of the present disclosure, the organic light-emitting display panel may be a top-emitting display panel or a bottom-emitting display panel. When the organic light-emitting display panel is a top emitting display panel, the anode 10 is a reflective electrode, and the cathode 30 is a transparent electrode. When the organic light-emitting display panel is a bottom-emitting display panel, the anode 10 is a transparent electrode, and the cathode 30 is a reflective electrode. Optionally, the reflective electrode may include metal, and the metal may be aluminum, gold or silver, etc. the transparent electrode may be made of light-transmitting metal oxides such as ITO, IZO, and ZnO. The reflective electrode may be made of metals such as Ag, Mg, Al, Pt, Pd, Au, Ni, Nd, Ir, Cr, Li, and Ca.

In embodiments of the present disclosure, a material of the light-emitting layer 21 includes an organic light-emitting material. The light-emitting layers 21 may include at least one of blue light-emitting layers, green light-emitting layers, red light-emitting layers, or white light-emitting layers. The material of the light-emitting layer 21 includes a host compound material and a dopant material. Compared with conventional host material combinations or host materials with a single component, a combination of the above specific materials can significantly improve a comprehensive performance of the organic electroluminescent devices, such as spectrum, voltage, luminous efficiency, and lifetime. Optionally, in an embodiment of the present disclosure, the host compound material may include a carbazolyl compound, and the dopant material may include metal complexes, organic complexes, or dyes, such as fluorescent dyes, phosphorescent materials, etc. Adding different dopants can achieve different colors of light emission.

In embodiments of the present disclosure, two adjacent quantum well units 20 share one barrier layer 22. That is, one barrier layer 22 is provided between the light-emitting layers 21 of two adjacent quantum well units 20, which is conducive to saving the process. Of course, in other embodiments, two adjacent quantum well units 20 may not share one barrier layer 22.

In order to avoid carrier imbalance, in an embodiment of the present disclosure, a material of the barrier layer 22 is a neutral material. Optionally, the material of the barrier layer 22 includes a methyl cyclopentenolone (MCP) material or a CBP (4,4-bis(9-carbazole)biphenyl) material.

It should be noted that a thickness of the barrier layer 22 is too thin to confine the electrons, the holes, and the excitons in the light-emitting layers 21, and the thickness of the barrier layer 22 is too thick will greatly reduce the ability of transmitting of the electrons and the holes to the quantum well unit 20 in the next layer. Therefore, in embodiments of the present disclosure, the thickness of the barrier layer 22 in the quantum well unit 20 is greater than or equal to 2 nanometers, and is less than or equal to 20 nanometers.

In embodiments of the present disclosure, thicknesses of the barrier layers 22 of a same quantum well unit 20 are equal, and thickness of the barrier layers 22 of different quantum well units 20 are also equal. Thicknesses of the light-emitting layers 21 of different the quantum well units 20 are also equal. Of course, in other embodiments, the above thicknesses may also be designed to be different.

The plurality of quantum well units 20 in the embodiments of the present disclosure are stacked to form a stacked structure, which can effectively disperse the excitons in the light-emitting layers 21 equilibrium in different areas. Even if some of the carriers are not confined by one of the quantum well units 20, the excess carriers will also be captured by the quantum well unit 20 of the next layer, so that composite luminescence can be achieved, which is conducive to improving the luminous efficiency of the device. Furthermore, the quantum well unit 20 includes the barrier layers 22 disposed on both sides of the light-emitting layer 21. In a first aspect, the barrier layers 22 can prevent energy diffusion from the light-emitting layer 21 to the adjacent layer causing energy loss, thereby ensuring the full use of energy. In a second aspect, the barrier layers 22 can effectively confine the carriers in the light-emitting layer 21, so that the light-emitting layer 21 can make full use of the injected carriers, which is conducive to improving the utilization rate of the excitons, and preventing device aging and attenuation caused by excess of the carriers with single type, excessive exciton concentration, etc. In a third aspect, the barrier layers 22 can avoid leakage current, which is conducive to improving the life of the organic light-emitting display panel.

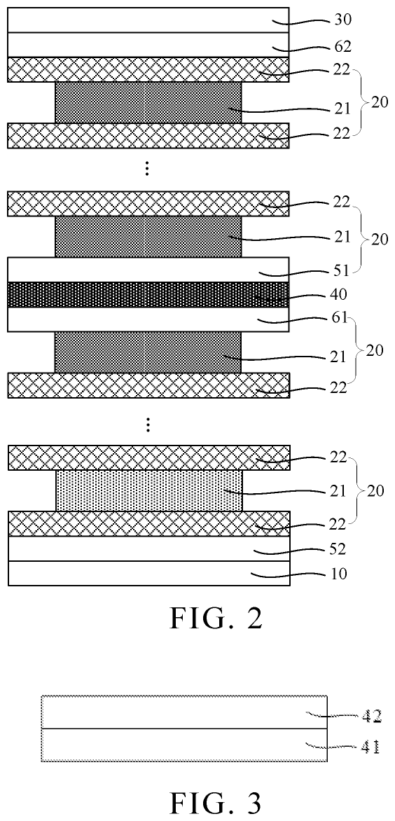

In embodiments of the present disclosure, referring to FIG. 2, a structure illustrated in FIG. 2 differs from the structure illustrated in FIG. 1 in that the quantum well unit 20 immediately adjacent to the charge generation layer 40 and close to the anode 10 includes a first electron transport layer 61, and the quantum well unit 20 immediately adjacent to the charge generation layer 40 and close to the cathode 30 includes a first hole transport layer 51.

It is understood that the first hole transport layer 51 is configured to transmit the holes generated by the charge generation layer 40, and the first electron transport layer 61 is configured to transmit the electrons generated by the charge generation layer 40, so as to ensure that the holes and the electrons generated by the charge generation layer 40 can be quickly transmitted through the first hole transport layer 51 and the first electron transport layer 61, respectively, to prevent the holes and the electrons from recombining at the charge generation layer 40 to form excitons, which is conducive to improving the luminous efficiency of the device.

In addition, in embodiments of the present disclosure, the first hole transport layer 51 and the first electron transport layer 61 play the role of the barrier layer 22. Therefore, the first hole transport layer 51 may serve as the barrier layer 22 of the quantum well unit 20 immediately adjacent to the charge generation layer 40 and close to the anode 10, and the first electron transport layer 61 may serve as the barrier layer 22 of the quantum well unit 20 immediately adjacent to the charge generation layer 40 and close to the cathode 30. The first hole transport layer 51 and the first electron transport layer 61 are configured to correspondingly prevent the excitons in the light-emitting layers 21 of the quantum well units 20 from being transported to the charge generation layer 40, which may result in the holes and the electrons at the charge generation layer 40 quenching, so as to improve the stability of the charge generation layer 40.

In embodiments of the present disclosure, the first hole transport layer 51 should be selected with a material having a high hole mobility, and the first electron transport layer 61 should be selected with a material having a high electron mobility.

Referring to FIG. 3, in embodiments of the present disclosure, the charge generation layer 40 includes an n-type charge generation layer 41 and a p-type charge generation layer 42 disposed in layers. The n-type charge generation layer 41 is disposed between the first electron transport layer 61 and the p-type charge generation layer 42, and the p-type charge generation layer 42 is disposed between the n-type charge generation layer 41 and the first hole transport layer 51. It is understood that the charge generation layer 40 can be compared to a stacked structure which is superimposed with two single-layer devices of the n-type charge generation layer 41 and the p-type charge generation layer 42. under the same brightness, the two single-layer devices each account for half of the brightness of the luminescence. Therefore, the driving current can be reduced to about half of the original, so that the driving current of the device can be effectively reduced, the luminous efficiency of the device is doubled, and the life of the device is greatly extended.

It should be noted that the n-type charge generation layer 41 is made of an N-type doped material of partial electron transport, and the p-type charge generation layer 42 is made of a P-type doped material of partial hole transport. The n-type charge generation layer 41 and the p-type charge generation layer 42 together constitute a PN junction to produce dipoles. Under the action of the electric field, the PN junction separates P-type transport holes and N-type transport electrons, the P-type transport holes are transmitted to the side close to the cathode 30, and the N-type transport electrons are transmitted to the side close to the anode 10.

In embodiments of the present disclosure, the material of the charge generation layer 40 may employ a material system with strong charge-generating ability. Optionally, a material of the p-type charge generation layer 42 includes one or more combinations of NPB (N,N′-BIS(1-naphthyl)-N,N′-diphenyl-1,1′-biphenyl-4-4′-diamine): MOO₃ (molybdenum trioxide), m-MTDATA (4,4′,4′-tris(N-3-methylphenyl-N-phenylamino)triphenylamine):HAT-CN (11-hexacyano-1), and TCTA (4,4′,4″-tris(carbazol-9-yl)triphenylamine): WO₃ (tungsten trioxide), and a material of the n-type charge generation layer 41 includes Bepp2 (bis(2-hydroxyphenylpyridine)beryllium):Yb (ytterbium), PO-T2T (2,4,6-Tris[3-(diphenylphosphino) phenyl]-1,3,5-triazine): iBphen:Yb (ytterbium), and Bphen(o-diazophene): CsCO₃ (cesium carbonate).

It should be noted that, based on the arrangement of the charge generation layer 40, the embodiments of the present disclosure may be provided with a larger number of the quantum well units 20 for device efficiency improvement. In practice, an optimal number of the quantum well units 20 may be determined by simulation experiments. Specifically, the optimal number of the quantum well units 20 may be determined according to the current efficiency and the driving voltage of the device. Simulation results carried out by the inventor show that there is a parabola-like relationship curve between the optimal number of the quantum well units 20 and the current efficiency of the device. The optimal number of the quantum well units 20 corresponds to the optimal current efficiency of the device, and the driving voltage does not increase significantly. In general, an increase amplitude of the driving voltage is not more than 2.5V.

In order to ensure that the luminescence effect of the two light-emitting units is consistent, in embodiments of the present disclosure, the optimal number of the quantum well units 20 is set to an even number. That is, the plurality of quantum well units 20 include an even number of the quantum well units 20. A number of the quantum well units 20 located on the side of the charge generation layer 40 close to the anode 10 is equal to a number of the quantum well units 20 located on the side of the charge generation layer 40 close to the cathode 30, thereby ensuring that the number of the carriers injected from the charge generation layer 40 to both sides thereof is consistent.

Optionally, the number of the quantum well units 20 can be 2, 4, 6, 8, etc., which should be selected according to the actual situations.

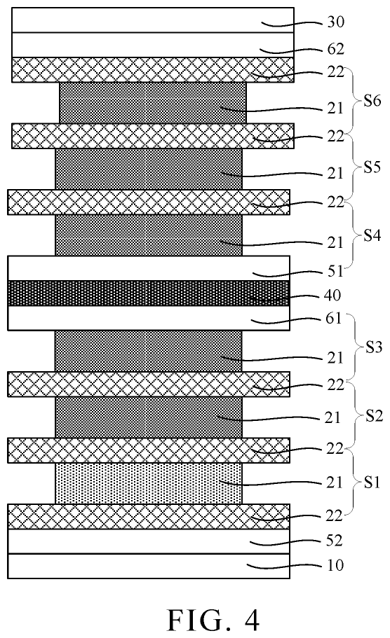

For example, referring to FIG. 4, the number of the quantum well units 20 is 6, i.e., the organic light-emitting display panel includes six quantum well units 20. The six quantum well units 20 are a first quantum well unit S1, a second quantum well unit S2, a third quantum well unit S3, a fourth quantum well unit S4, a fifth quantum well unit S5, and a sixth quantum well unit S6 disposed between the anode 10 and the cathode 30. The charge generation layer 40 is disposed between the third quantum well unit S3 and the fourth quantum well unit S4. The first hole transport layer 51 may serve as the barrier layer 22 of the third quantum well unit S3, and the first electron transport layer 61 may serve as the barrier layer 22 of the fourth quantum well unit S4.

Furthermore, the organic light-emitting display panel generates two kinds of excitons when electroluminescence, one kind of excitons are trilinear excitons, and the other kind of excitons are singlet excitons. Among them, the singlet exciton is in a singlet state, and the trilinear exciton is in a trilinear state. Since a barrier of the quantum well unit 20 mainly comes from a higher energy level of the barrier layer 22, the higher barrier will lead to an increase in the driving voltage of the device, and the transport of the holes and the electrons will gradually become more and more difficult with the increase of barriers, and finally as the number of quantum wells exceeds the optimal number, the balance of the electrons and the holes will be broken. In order to ensure that the electrons and the holes are confined within the light-emitting layers 21, in embodiments of the present disclosure, an energy level difference between a trilinear energy level of the host material of the barrier layer 22 and a trilinear energy level of the host material of the light-emitting layer 21 is greater than 0.2 eV, and an energy level difference between a singlet energy level of the host material of the barrier layer 22 and a singlet energy level of the host material of the light-emitting layer 21 is greater than 0.2 eV.

In other words, the trilinear energy level of the host material of the barrier layer 22 is greater than the trilinear energy level of the host material of the light-emitting layer 21, and the energy level difference between the two is controlled within a suitable range, so that the barrier layers 22 can confine the electrons and the holes within the light-emitting layer 21. Furthermore, the singlet energy level of the host material of the barrier layer 22 is greater than the singlet energy level of the host material of the light-emitting layer 21, and the energy level difference between the two is controlled within a suitable range, so that the barrier layer 22 can confine the electrons and the holes within the light-emitting layer 21, thereby reducing energy loss, and improving the luminous efficiency of the device.

Specifically, a range of the trilinear energy level of the host material of the barrier layer 22 is 2.5 eV-6.0 eV, and a range of the energy level of the trilinear energy level of the host material of the light-emitting layer 21 is 2.0 eV-5.0 eV. A range of the singlet energy level of the host material of the barrier layer 22 is 2.5 eV-6.0 eV, and a range of the singlet energy level of the host material of the light-emitting layer 21 is 2.0 eV-5.0 eV.

Furthermore, an energy level difference between a highest occupied molecular orbital (HOMO) energy level of the host material of the barrier layer 22 and a HOMO energy level of the host material of the light-emitting layer 21 is greater than 0.2 eV, and an energy level difference between a lowest unoccupied molecular orbital (LUMO) energy level of the host material of the barrier layer 22 and a LUMO energy level of the host material of the light-emitting layer 21 is greater than 0.2 eV, so as to further ensure that the electrons and the holes are confined within the light-emitting layer 21, thereby reducing energy loss and improving the luminous efficiency of the device.

Based on the above description, in embodiments of the present disclosure, the barrier layer 22 has a higher singlet energy level, a higher three-wire energy level, a higher LUMO energy level, and a higher HOMO energy level relative to the light-emitting layer 21, which can ensure that the electrons and the holes are confined within the light-emitting layer 21, thereby reducing energy loss and improving the luminous efficiency of the device.

Of course, the organic light-emitting display panel further includes a hole injection layer (not shown) and an electron injection layer (not shown). The hole injection layer is disposed between the anode 10 and the plurality of quantum well units 20 to promote the injection of the holes. The electron injection layer is disposed between the anode 10 and the plurality of quantum well units 20 to promote the injection of the electrons. As illustrated in FIG. 3, the hole injection layer is disposed between the anode 10 and the first quantum well unit S1, and the electron injection layer is disposed between the cathode 30 and the sixth quantum well unit S6.

The organic light-emitting display panel further includes a substrate and a driving circuit layer disposed on the substrate. The driving circuit layer is configured to drive the display devices to emit light. The driving circuit layer is disposed between the substrate and the anode 10. The driving circuit layer includes an active matrix drive circuit or a passive matrix drive circuit. Furthermore, the organic light-emitting display panel further includes a pixel definition layer, a package layer, and other functional structures not illustrated.

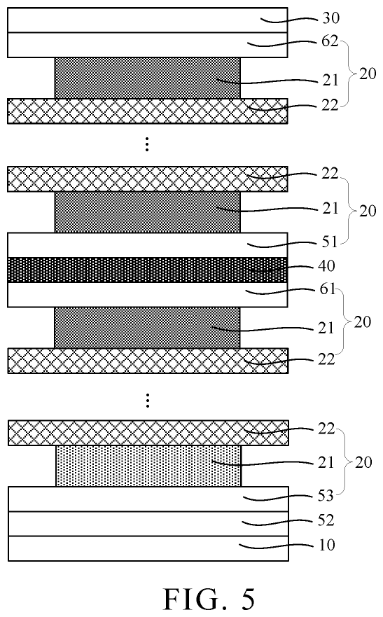

In addition, referring to FIG. 5, a structure illustrated in FIG. 5 differs from the structure illustrated in FIG. 2 in that the organic light-emitting display panel includes a second hole transport layer 52 disposed on a side of the anode 10 close to the cathode 30. The barrier layer 22 of the quantum well unit 20 immediately adjacent to the anode 10 includes a third hole transport layer 53, and the barrier layer 22 of the quantum well unit 20 immediately adjacent to the cathode 30 includes a second electron transport layer 62.

The second hole transport layer 52 plays a role of transmitting the holes injected from the anode 10, and the second electron transport layer 62 plays a role of transmitting the electrons injected from the cathode 30. The third hole transport layer 53 may play a role of the barrier layer 22, so as to confine the excitons within the light-emitting layer 21, block the excitons from energy transfer, and reduce energy loss, thereby improving the luminous efficiency of the organic light-emitting device. At the same time, the third hole transport layer 53 has a higher LUMO energy level and transport hole characteristics, which can prevent the electrons from being transported through the third hole transport layer 53. The second electron transport layer 62 has a higher LUMO energy level and transport electron characteristics, which can prevent the holes from being transported through the second electron transport layer 62.

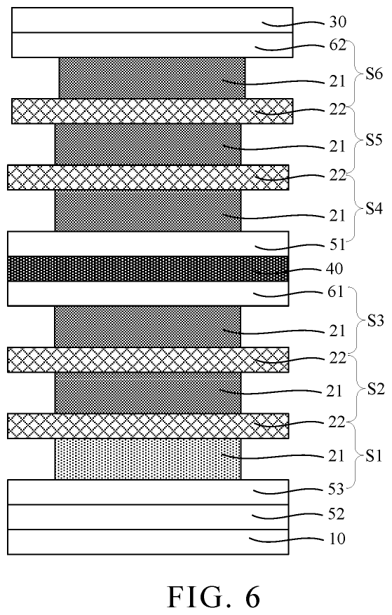

As illustrated in FIG. 6, the third hole transport layer 53 may be used as the barrier layer 22 of the first quantum well unit S1, and the second electron transport layer 62 may be used as the barrier layer 22 of the sixth quantum well unit S6. The hole injection layer (not shown in the figures) is disposed between the anode 10 and the second hole transport layer 52, and the electron injection layer (not shown in the figures) is disposed between the cathode 30 and the second electron transport layer 62.

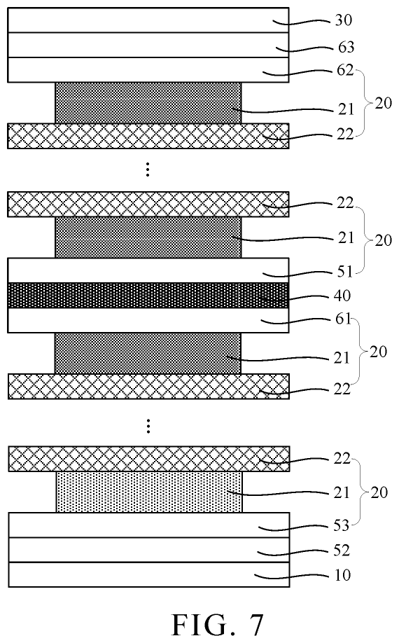

In addition, referring to FIG. 7, a structure illustrated in FIG. 7 differs from the structure illustrated in FIG. 2 in that the organic light-emitting display panel may further include a third electron transport layer 63. The third electron transport layer 63 and the second electron transport layer 62 are stacked. Specifically, the third electron transport layer 63 is disposed on a side of the second electron transport layer 62 away from the cathode 30, or the third electron transport layer 63 is disposed between the second electron transport layer 62 and the cathode 30. Similar to a double-layer structure formed by stacking the second hole transport layer 52 and the third hole transport layer 53, the third electron transport layer 63 and the second electron transport layer 62 are stacked to form another double-layer structure, which can block the excitons from energy transfer to functional layers, and at the same time block transmission of the holes to the second electron transport layer 62 or the third electron transport layer 63.

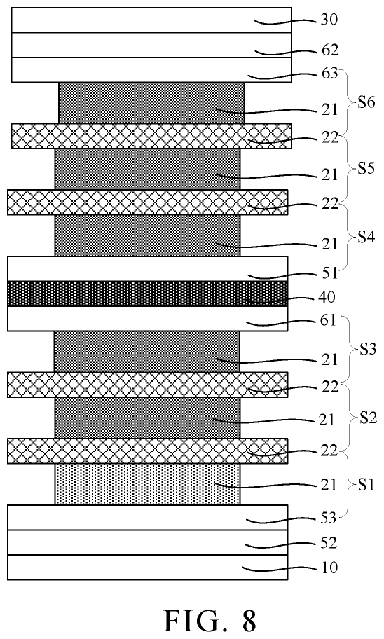

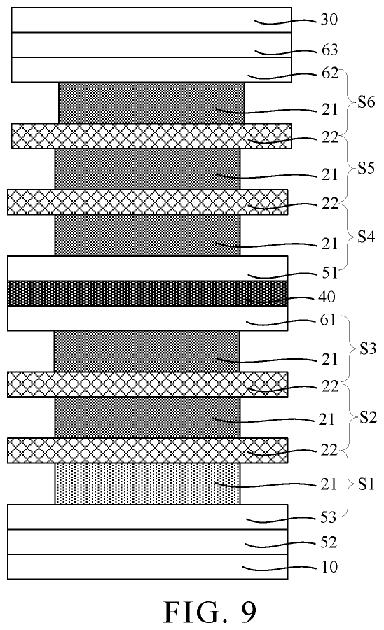

Referring to FIG. 8, when the third electron transport layer 63 is disposed on the side of the second electron transport layer 62 away from the cathode 30, the third electron transport layer 63 serves as the barrier layer 22 of the sixth quantum well unit S6. Referring to FIG. 9, when the third electron transport layer 63 is disposed between the second electron transport layer 62 and the cathode 30, the second electron transport layer 62 may serve as the barrier layer 22 of the sixth quantum well unit S6.

Embodiments of the present disclosure also provide a method for manufacturing an organic light-emitting display panel, including following steps:
S1, forming an anode 10;
S2, forming a plurality of quantum well units 20 on a side of the anode 10;
S3, forming a charge generation layer 40 on the quantum well units 20;
S4, forming a plurality of quantum well units 20 on the charge generation layer 40; and
S5, forming a cathode 30 on the quantum well units 20.

Herein, the charge generation layer 40 is disposed between two adjacent ones of the plurality of quantum well units 20, is configured to inject the electrons into the light-emitting layers 21 of at least some of the quantum well units 20 located on a side of the charge generation layer 40, and is configured to inject the holes into the light-emitting layers 21 of at least some of the quantum well units 20 located on another side of the charge generation layer 40.

Specifically, the step SI further includes the following steps:
S10, providing a substrate;
S20, forming a driving circuit layer on the substrate; and
S30, forming the anode 10 on the driving circuit layer.

Embodiments of the present disclosure also provide display devices. The display device includes a processor and an organic light-emitting display panel in any one of the above embodiments. the processor may include driver chips driving the organic light-emitting display panel to emit light. The display device may be a mobile phone, a tablet computer, an e-reader, an electronic display screen, a laptop, a mobile phone, an augmented reality (AR) \ virtual reality (VR) device, a media player, a wearable device, a digital camera, a car navigation system, etc.

The present disclosure provides organic light-emitting display panels and display devices. The organic light-emitting display panel includes an anode, a cathode, and a plurality of quantum well units stacked between the anode and the cathode. Each quantum well unit includes a light-emitting layer and barrier layers disposed on both sides of the light-emitting layer. In the present disclosure, the charge generation layer is provided between two adjacent ones of the plurality of quantum well units, the charge generation layer separates electrons and holes under an action of an applied electric field, the separated electrons are injected into the light-emitting layers of at least some of the quantum well units located on a side of the charge generation layer, and the separated holes are injected into the light-emitting layers of at least some of the quantum well units located on the other side of the charge generation layer, and the holes and electrons are recombined in the light-emitting layers. Based on this, the holes and the electrons from the anode and the cathode do not need to be transmitted to each of the light-emitting layers of the quantum well units, which reduces the transmission difficulty of the holes and the electrons, and reduces the driving current of the device, which is conducive to maintaining carrier balance and improving the efficiency and lifetime of the device.

Embodiments of the present disclosure have been described above in detail. In this paper, specific examples are used to illustrate the principle and implementation of the invention. The description of the above embodiments is only used to help understand the method of the present disclosure and its core idea. Those skilled in the art can make various changes and modifications without departing from the spirit of the present disclosure. Therefore, the described embodiments are not intended to limit the present disclosure.

What is claimed is:

1. An organic light-emitting display panel, comprising:
an anode;
a cathode, arranged opposite to the anode;
a plurality of quantum well units, stacked between the anode and the cathode, each of the quantum well units comprising a light-emitting layer and barrier layers disposed on both sides of the light-emitting layer; and
a charge generation layer, disposed between two adjacent ones of the plurality of quantum well units, configured to inject electrons into the light-emitting layer of each of some of the quantum well units located on a side of the charge generation layer, and configured to inject holes into the light-emitting layer of each of some of the quantum well units located on another side of the charge generation layer.

2. The organic light-emitting display panel according to claim 1, wherein one quantum well unit of the plurality of quantum well units adjacent to the charge generation layer and close to the anode comprises a first electron transport layer serving as one of the barrier layers thereof, and one quantum well unit of the plurality of quantum well units adjacent to the charge generation layer and close to the cathode comprises a first hole transport layer serving as one of the barrier layers thereof.

3. The organic light-emitting display panel according to claim 2, wherein the charge generation layer comprises:
an n-type charge generation layer; and
a p-type charge generation layer,
wherein the n-type charge generation layer is disposed between the first electron transport layer and the p-type charge generation layer, and the p-type charge generation layer is disposed between the n-type charge generation layer and the first hole transport layer.

4. The organic light-emitting display panel according to claim 1, wherein an energy level difference between a trilinear energy level of a host material of the barrier layers and a trilinear energy level of a host material of the light-emitting layer is greater than 0.2 eV; and
an energy level difference between a singlet energy level of the host material of the barrier layers and a singlet energy level of the host material of the light-emitting layer is greater than 0.2 eV.

5. The organic light-emitting display panel according to claim 4, wherein an energy level difference between a highest occupied molecular orbital (HOMO) energy level of the host material of the barrier layers and a HOMO energy level of the host material of the light-emitting layer is greater than 0.2 eV; and
an energy level difference between a lowest unoccupied molecular orbital (LUMO) energy level of the host material of the barrier layers and a LUMO energy level of the host material of the light-emitting layer is greater than 0.2 eV.

6. The organic light-emitting display panel according to claim 4, wherein a range of the trilinear energy level of the host material of the barrier layers is 2.5 eV-6.0 eV, and a range of the trilinear energy level of the host material of the light-emitting layer is 2.0 eV-5.0 eV; and
a range of the singlet energy level of the host material of the barrier layers is 2.5 eV-6.0 eV, and a range of the singlet energy level of the host material of the light-emitting layer is 2.0 eV-5.0 eV.

7. The organic light-emitting display panel according to claim 1, wherein the plurality of quantum well units include an even number of quantum well units, and a number of the quantum well units located on a side of the charge generation layer adjacent to the anode is equal to a number of the quantum well units located on a side of the charge generation layer adjacent to the cathode.

8. The organic light-emitting display panel according to claim 1, further comprising a second hole transport layer disposed on a side of the anode adjacent to the cathode,
wherein one quantum well unit of the plurality of quantum well units immediately adjacent to the anode comprises a third hole transport layer serving as one of the barrier layers thereof; and
one quantum well unit of the plurality of quantum well units immediately adjacent to the cathode comprises a second electron transport layer serving as one of the barrier layers thereof.

9. The organic light-emitting display panel according to claim 1, further comprising:
a second hole transport layer and a third hole transport layer stacked on a side of the anode adjacent to the cathode; and
a second electron transport layer and a third electron transport layer stacked on a side of the cathode adjacent to the anode,
wherein one quantum well unit of the plurality of quantum well units immediately adjacent to the anode comprises one of the second hole transport layer and the third hole transport layer away from the anode serving as one of the barrier layers thereof, and one quantum well unit of the plurality of quantum well units immediately adjacent to the cathode comprises one of the second electron transport layer and the third electron transport layer away from the cathode serving as one of the barrier layers thereof.

10. The organic light-emitting display panel according to claim 1, wherein a thickness of each of the barrier layers is greater than or equal to 2 nanometers, and is less than or equal to 20 nanometers.

11. A display device, comprising an organic light-emitting display panel, wherein the organic light-emitting display panel comprises:
an anode;
a cathode, arranged opposite to the anode;
a plurality of quantum well units, stacked between the anode and the cathode, each of the quantum well units comprising a light-emitting layer and barrier layers disposed on both sides of the light-emitting layer; and
a charge generation layer, disposed between two adjacent ones of the plurality of quantum well units, configured to inject electrons into the light-emitting layer of each of some of the quantum well units located on a side of the charge generation layer, and configured to inject holes into the light-emitting layer of each of some of the quantum well units located on another side of the charge generation layer.

12. The display device according to claim 11, wherein one quantum well unit of the plurality of quantum well units adjacent to the charge generation layer and close to the anode comprises a first electron transport layer serving as one of the barrier layers thereof, and one quantum well unit of the plurality of quantum well units adjacent to the charge generation layer and close to the cathode comprises a first hole transport layer serving as one of the barrier layers thereof.

13. The display device according to claim 12, wherein the charge generation layer comprises:
an n-type charge generation layer; and
a p-type charge generation layer,
wherein the n-type charge generation layer is disposed between the first electron transport layer and the p-type charge generation layer, and the p-type charge generation layer is disposed between the n-type charge generation layer and the first hole transport layer.

14. The display device according to claim 11, wherein an energy level difference between a trilinear energy level of a host material of the barrier layers and a trilinear energy level of a host material of the light-emitting layer is greater than 0.2 eV; and
an energy level difference between a singlet energy level of the host material of the barrier layers and a singlet energy level of the host material of the light-emitting layer is greater than 0.2 eV.

15. The display device according to claim 14, wherein an energy level difference between a highest occupied molecular orbital (HOMO) energy level of the host material of the barrier layers and a HOMO energy level of the host material of the light-emitting layer is greater than 0.2 eV; and
an energy level difference between a lowest unoccupied molecular orbital (LUMO) energy level of the host material of the barrier layers and a LUMO energy level of the host material of the light-emitting layer is greater than 0.2 eV.

16. The display device according to claim 14, wherein a range of the trilinear energy level of the host material of the barrier layers is 2.5 eV-6.0 eV, and a range of the trilinear energy level of the host material of the light-emitting layer is 2.0 eV-5.0 eV; and
a range of the singlet energy level of the host material of the barrier layers is 2.5 eV-6.0 eV, and a range of the singlet energy level of the host material of the light-emitting layer is 2.0 eV-5.0 eV.

17. The display device according to claim 11, wherein the plurality of quantum well units include an even number of quantum well units, and a number of the quantum well units located on a side of the charge generation layer adjacent to the anode is equal to a number of the quantum well units located on a side of the charge generation layer adjacent to the cathode.

18. The display device according to claim 11, the organic light-emitting display panel further comprises a second hole transport layer disposed on a side of the anode adjacent to the cathode;
one quantum well unit of the plurality of quantum well units immediately adjacent to the anode comprises a third hole transport layer serving as one of the barrier layers thereof; and
one quantum well unit of the plurality of quantum well units immediately adjacent to the cathode comprises a second electron transport layer serving as one of the barrier layers thereof.

19. The display device according to claim 11, wherein the organic light-emitting display panel further comprises:
a second hole transport layer and a third hole transport layer stacked on a side of the anode adjacent to the cathode; and
a second electron transport layer and a third electron transport layer stacked on a side of the cathode adjacent to the anode; and
wherein one quantum well unit of the plurality of quantum well units immediately adjacent to the anode comprises one of the second hole transport layer and the third hole transport layer away from the anode serving as one of the barrier layers thereof, and one quantum well unit of the plurality of quantum well units immediately adjacent to the cathode comprises one of the second electron transport layer and the third electron transport layer away from the cathode serving as one of the barrier layers thereof.

20. The display device according to claim 11, wherein a thickness of each of the barrier layers is greater than or equal to 2 nanometers, and is less than or equal to 20 nanometers.
